(19) United States
(12) Patent Application Publication
(10) Pub. No.: US 2013/0064975 A1
(43) Pub. Date: Mar. 14, 2013

(54) VAPOR TRANSPORT DEPOSITION SYSTEM AND METHOD EMPLOYING REMOVABLE SHIELDS

(71) Applicant: Stephen P. Murphy, Perrysburg, OH (US)

(72) Inventor: Stephen P. Murphy, Perrysburg, OH (US)

(21) Appl. No.: 13/611,591

(22) Filed: Sep. 12, 2012

Related U.S. Application Data
(60) Provisional application No. 61/533,576, filed on Sep. 12, 2011.

(51) Int. Cl. C23C 16/44

(52) U.S. Cl. 427/248.1; 118/715; 118/724

(57) ABSTRACT

A method and system includes removable shields arranged inside a deposition chamber to prevent vaporized material from accumulating on the walls of the chamber. The removable shields can be removed for cleaning.

### CROSS REFERENCE TO RELATED APPLICATION

This application claims priority to Provisional Application No. 61/533,576, filed on Sep. 12, 2011, the disclosure of which is incorporated by reference in its entirety.

### FIELD OF THE INVENTION

Embodiments described herein relate generally to methods and apparatus used to fabricate a photovoltaic device, and more specifically to methods and apparatus for reducing contamination of a vapor transport deposition chamber.

### BACKGROUND OF THE INVENTION

In the manufacture of a photovoltaic device, various materials, including semiconductor material, are deposited on a glass substrate. This may be accomplished by vaporizing the material in a vapor transport deposition chamber and directing the vaporized material towards a substrate surface, e.g., glass, such that the vaporized material condenses and is deposited as a film on the substrate.

In such a vapor transport deposition chamber, the vaporized material condenses not only on the substrate or substrate surface, but also accumulates on the walls and heating elements of the deposition chamber. This build up of material can result in corrosion of the heating elements and non-uniform chamber temperature, among other issues. To alleviate this, a vapor transport deposition chamber must be shut down and the material buildup must be scraped off, which disrupts production and causes costly delay. What is needed is a method and apparatus to quickly remove material buildup within a vapor transport deposition chamber.

### BRIEF DESCRIPTION OF THE DRAWINGS

FIG. 1 shows a system for depositing a material on a glass sheet substrate.

FIG. 2 shows a material supply for introducing a material powder and a carrier gas into a distributor assembly.

FIG. 3 shows a perspective view of a line drawing of a vapor transport deposition chamber.

FIG. 4 shows a cut-away end view of a vapor transport deposition chamber according to an aspect described herein.

FIG. 5 shows a cut-away side view of a vapor transport deposition chamber according to another aspect described herein.

FIG. 6 shows a cut-away end view of a vapor transport deposition chamber according to another aspect described herein.

FIGS. 7A and 7B show removable shields according to another aspect described herein.

FIG. 8 shows a cut-away end view of a vapor transport deposition chamber according to another aspect described herein.

FIG. 9 shows a cut-away end view of a vapor transport deposition chamber according to another aspect described herein.

FIG. 10 shows a cut-away side view of a vapor transport deposition chamber according to another aspect described herein.

### DETAILED DESCRIPTION OF THE INVENTION

A solid material such as a semiconductor powder and carrier gas for carrying the semiconductor powder can be introduced into a heated permeable tubular chamber, where the solid material is vaporized. The vapor and carrier gas then pass through the walls of the heated permeable chamber into a shroud surrounding the chamber. The shroud can include an opening through which the vapor is directed toward a surface of a substrate, such as a glass substrate, where it is deposited as a film. For purposes of description herein, embodiments will describe the use of a vaporized semiconductor material, but it should be understood that the embodiments may be used with other vaporizable materials as well. An apparatus and method for depositing a vaporizable semiconductor material as a film on a glass substrate is described; for example, in U.S. Pat. No. 7,910,166, the disclosure of which is herein incorporated by reference in its entirety.

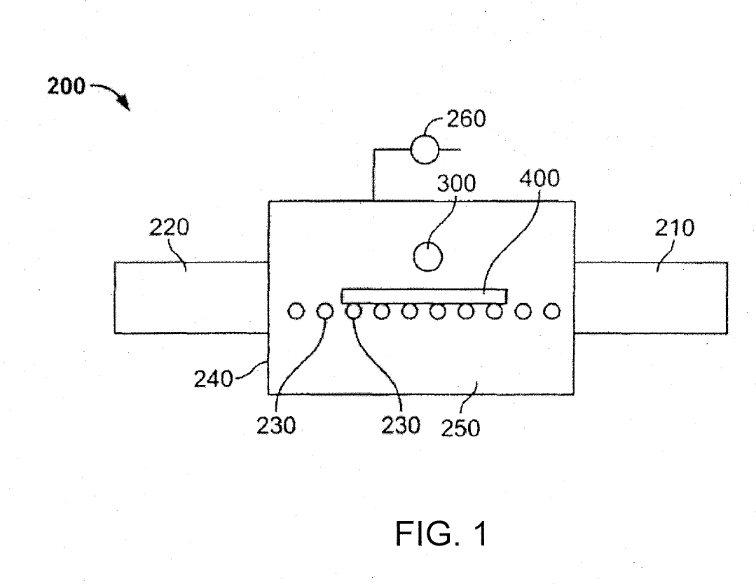

With reference to FIG. 1 of the drawings, a vapor deposition system 200 includes a vaporized material distributor assembly 300 and a housing 240 defining a vapor transport deposition chamber 250 in which a material is deposited on a substrate 400, for example, a glass sheet. Housing 240 includes an entry station 210 and an exit station 220. Entry station 210 and exit station 220 can be constructed as load locks or as slit seals through which substrate 400 enters and exits the vapor transport deposition chamber 250. The housing 240 can be heated in any suitable manner such that its processing chamber can be maintained at a desired deposition temperature, for example, by heating coils arranged within the housing 240. The distributor temperature can be 500 degrees to 1200 degrees C. Substrate 400 can be heated during the processing to a desired substrate temperature. The substrate temperature can be 200 degrees to 650 degree C. Substrate 400 can be transported by any appropriate means such as rollers 230 or a conveyor belt, preferably driven by an attached electric motor.

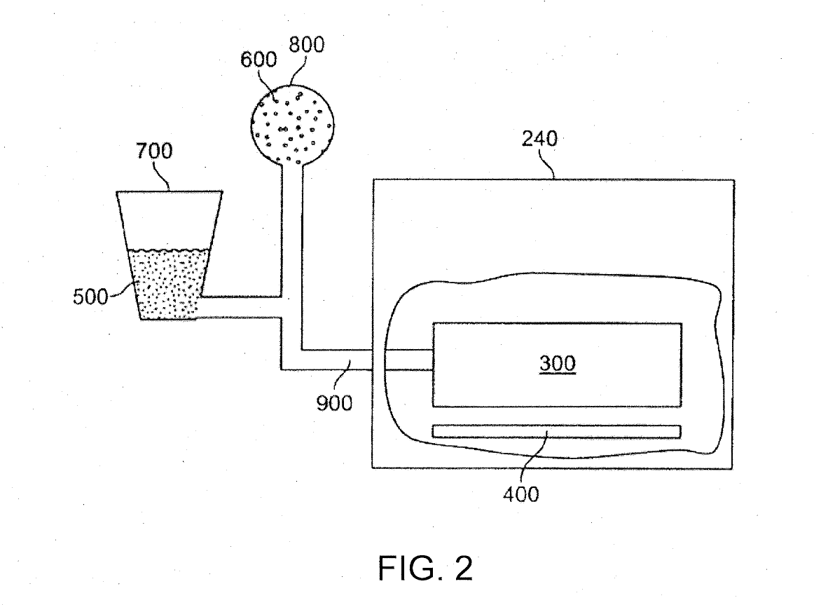

With reference to FIG. 2, distributor assembly 300 contained in housing 240 is connected by feed tube 900 to a material supply which can include a hopper 700 containing a powder 500 and a carrier gas source 800 containing an appropriate carrier gas 600. Powder 500 can contact carrier gas 600 in feed tube 900, and both carrier gas 600 and powder 500 are introduced into distributor assembly 300.

After carrier gas 600 and powder 500 are introduced into distributor assembly 300, which includes a heated material vaporizer and a vapor distributor, the powder material 500 is vaporized in the vaporizer and flows through the distributor of the distributor assembly 300 and onto substrate 400. In some applications, the carrier gas may be augmented by a process gas which reacts with the vaporized powder to produce a desired vapor deposition composition. The material vapor composition from distributor assembly 300 condenses as a uniform thin film on the substrate 400.

Cadmium telluride and cadmium sulfide are examples of materials which have been successfully deposited on a glass substrate using deposition system 200 in the manufacture of photovoltaic modules. However, it should be appreciated that other semiconductor and non-semiconductor materials can be deposited in the manufacture of other products. Also, dopants may be added to the powder 500 to enhance desired properties of the resulting film.

A vacuum may be provided in the processing chamber 250 at about 0.5 to 760 Torr for the processing of thin films for use in photovoltaic modules. In that connection, as illustrated in FIG. 1, the processing system 200 includes a suitable exhaust pump 260 for removing the carrier gas 600 both initially and continuously from the processing chamber 250.

The carrier gas 600 supplied from the source 800 can be helium, which has been found to increase the glass temperature range and the pressure range that provide film characteristics such as good deposition density and good bonding. Alternatively, the carrier gas can be another gas such as nitrogen, neon, argon or krypton, or combinations of these gases. It is also possible for the carrier gas to include an amount of a reactive gas such as oxygen that can advantageously affect growth properties of the material. A flow rate of 0.3 to 10 standard liters per minute of the carrier gas has been determined to be sufficient to provide the material flow to distributor assembly 300 for deposition of semiconductor material on a substrate.

It should be recognized that multiple material supplies having multiple hopper and multiple carrier gas sources may also be used to introduce carrier gas and material into the distributor assembly 300. A single material supply is shown in FIG. 2 for the sake of clarity.

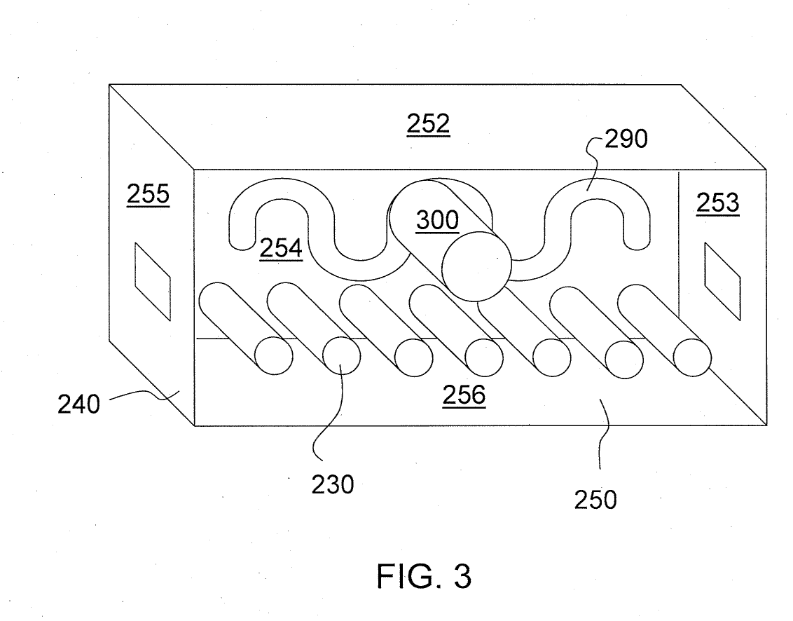

FIG. 3 shows a perspective view of a vapor transport deposition chamber 250 of FIG. 1 that includes a side wall 254, top wall 252, bottom wall 256, and end walls 253, 255, which make up a portion of the housing 240 of the chamber 250. An additional side wall 258 is not shown in FIG. 3 to better show the inside of the chamber 250. A heating element 290 is mounted on side wall 254 and additional heating elements may be provided on an opposite side wall, as well as on other walls forming deposition chamber 250. Vaporized material exiting the distributor assembly 300 will condense not only on the surface of a substrate supported by rollers 230, but also accumulates on the walls 252, 253, 254, 255, 256 and heating element 290 of the chamber 250. This build up of solid material can result in corrosion of the heating element 290 and non-uniform deposition chamber temperature, among other issues. This build up of solid material must be periodically removed.

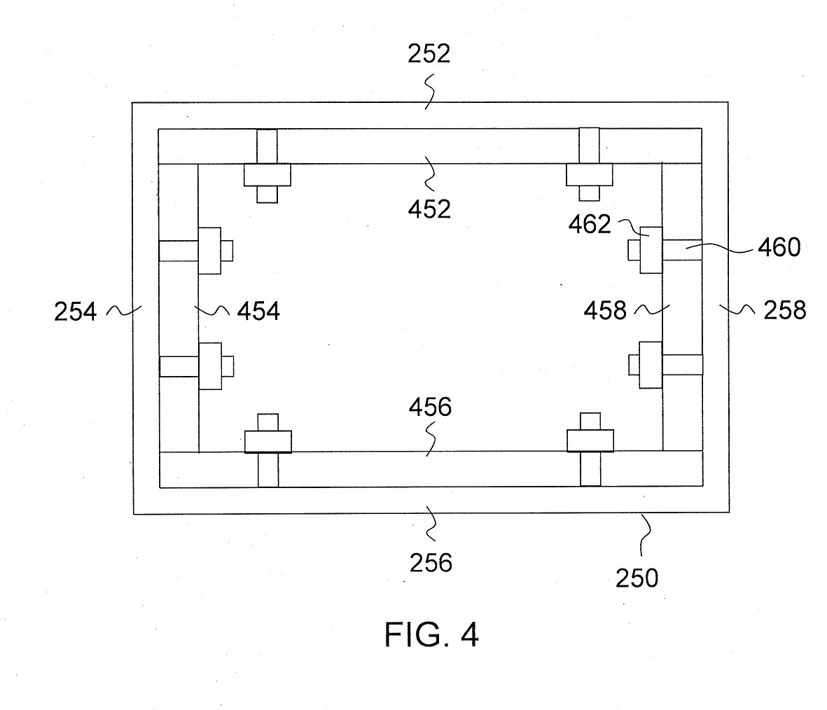

FIG. 4 shows a cut-away end view of a vapor transport deposition chamber 250 in accordance with an embodiment having removable shields 452, 454, 456, 458 affixed to the top wall 252, first side wall 254, bottom wall 256, and second side wall 258, respectively. The removable shields 452, 454, 456, 458 may cover a portion or all of their respective walls 252, 254, 256, 268. In various aspects, the removable shields 452, 454, 456, 458 may be formed of a material that has a low coefficient of thermal expansion, is capable of handling a high temperature environment, is mechanically strong, and is resistant to a corrosive environment, for example, a metal, such as stainless steel, or a composite material, such as carbon fiber may be used for the shields.

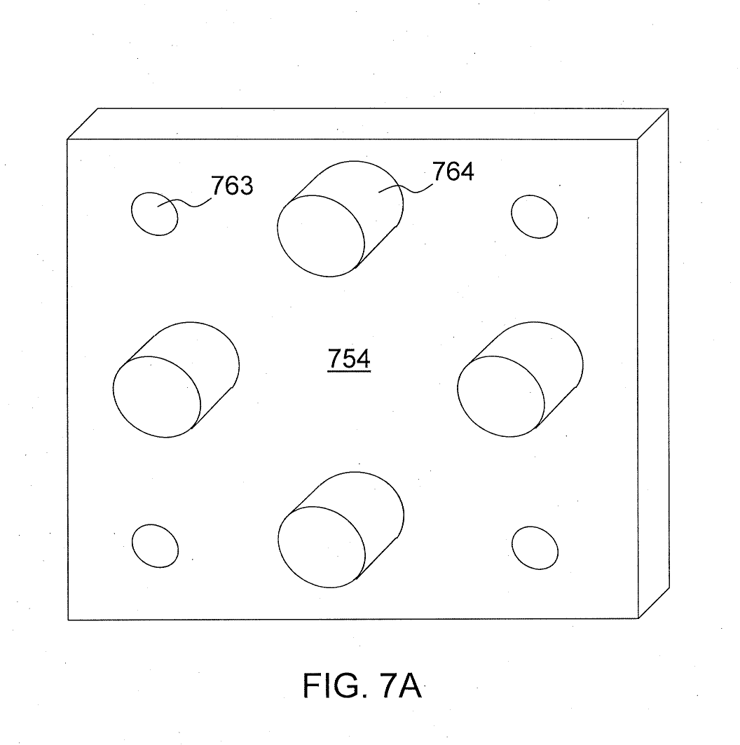

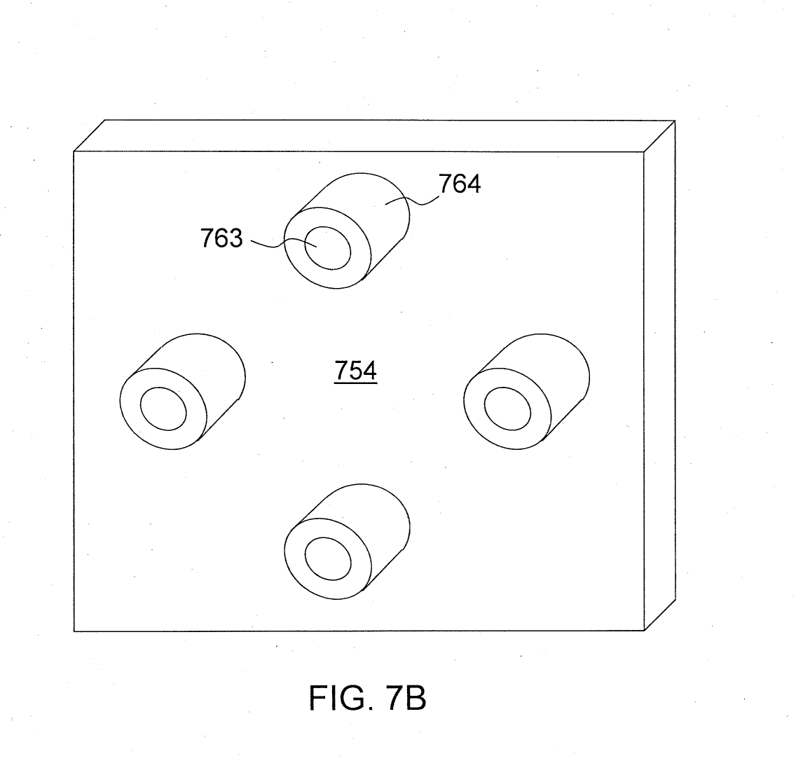

The removable shields 452, 454, 456, 458 may be mounted to the walls 252, 254, 256, 268 of the vapor transport deposition chamber 250 by passing one or more rods 460 through holes 763 (FIG. 7) in the removable shields. In one aspect, the rods 460 may be threaded shafts. In another aspect, the rods 460 may be attached to the walls by welding or may be screwed into the wall. The rods 460 do not extend through the walls 252, 254, 256, 268 of the vapor transport deposition chamber 250 so as to not create a passageway for vaporized material to escape the chamber.

The removable shields 452, 454, 456, 458 may be secured to the rods 640 by fasteners 462. In one aspect the fasteners 462 may be nuts if the rods 460 are threaded shafts. In another aspect, the fasteners 462 may be locking pins which engage with holes in the rods 460.

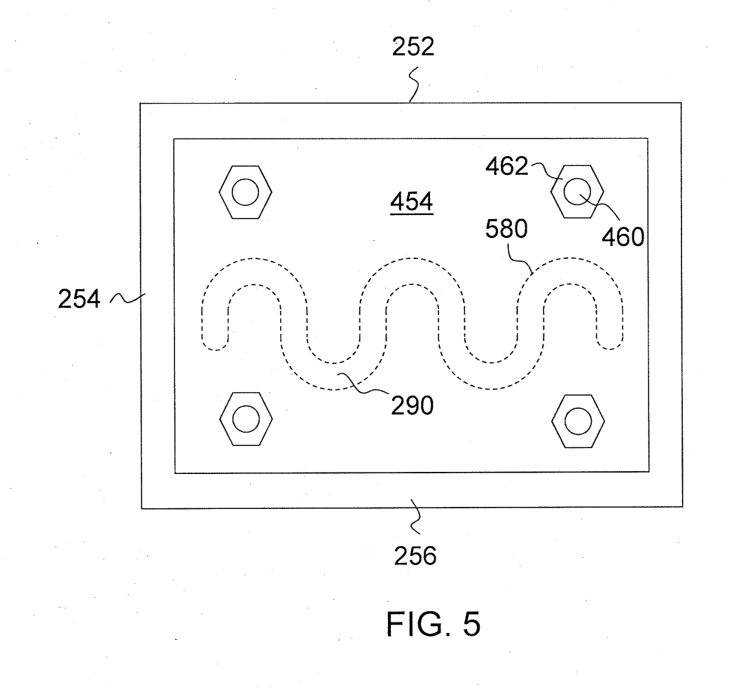

In the embodiment shown in FIG. 4, the removable shields 452, 454, 456, 458 are fitted directly against their respective walls 252, 254, 256, 268. As shown in FIG. 5, one or more of the removable shields 452, 454, 456, 458 may include an indentation 580 in a shape corresponding to the shape of heating element 290 to accommodate a heating element 290 of deposition chamber 250. When the removable shield 454 is fitted against the wall 254, the indentation 580 cups the heating element 290, forming a sealed chamber with the wall 254 to fully enclose the heating element 290. In FIG. 5, the indentation 580 is shown in dashed lines because it is sandwiched between the removable shield 454 and the wall 254. While the indentation 580 of FIG. 5 is shaped in a wave pattern, it should be understood that the shape of the indentation 580 may be varied to match a variety of shapes of heating elements 290 which can fit within a corresponding indentation 580 in a removable shield. In another embodiment, the removable shield 454 may include a cutout in the shape of the heating element 290, allowing the heating element 290 to be exposed to the interior of the chamber.

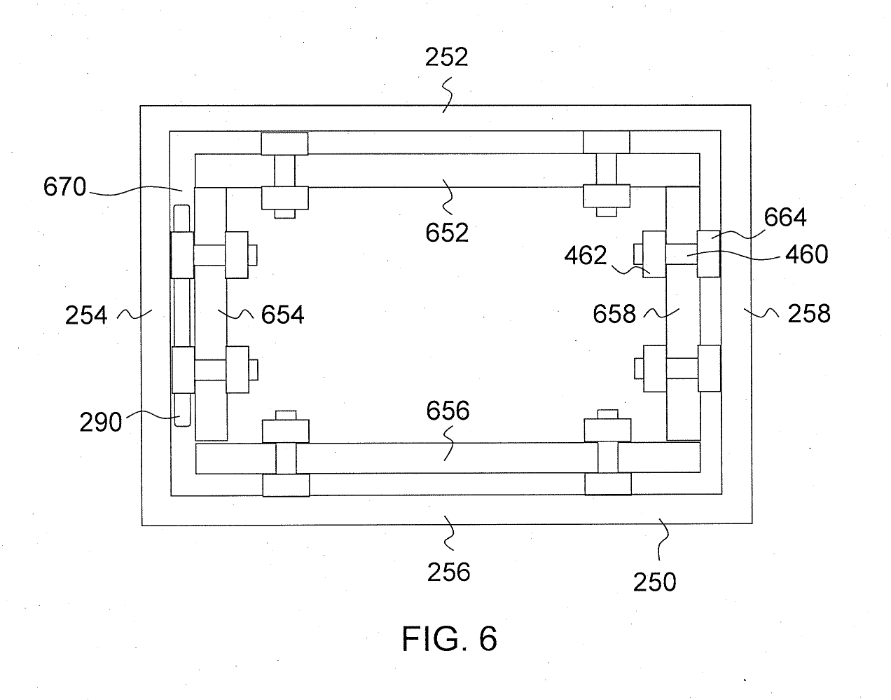

FIG. 6 shows another embodiment in which removable shields 652, 654, 656, 658 are held at a distance from respective walls 252, 254, 256, 268 by a number of stand-offs 664 arranged rods 460. The stand-offs 664 prevent at least one of the plurality of removable shields 652, 654, 656, 658 from directly contacting the walls of the vapor transport deposition chamber 250. The stand-offs 664 form a gap 670 between the removable shields 652, 654, 656, 658 and their respective walls 252, 254, 256, 268 that can accommodate a heating element 290 without the need for an indentation in the removable shields as in the FIG. 5 embodiment. The stand-offs 664 can be arranged on the rods 460 as shown in FIG. 6, or could be attached directly to the removable shields 652, 654, 656, 658 and/or the walls 252, 254, 256, 268 at locations other than the rods 460. The stand-offs 664 may be permanently or removably attached to the rods 460, removable shields 652, 654, 656, 658 and/or the walls 252, 254, 256, 268. For example, on the removable shield 754 shown in FIG. 7A, the stand-offs 764 are permanently attached directly to the removable shield 754 and are located away from the holes 763 used to accommodate the rods 460. On the removable shield 754 shown in FIG. 7B, the stand-offs 764 are permanently attached directly to the removable shield 754 and the holes 763 pass through the stand-offs 764. Rods 460, in turn, pass through holes 763 for mounting the heat shields in place.

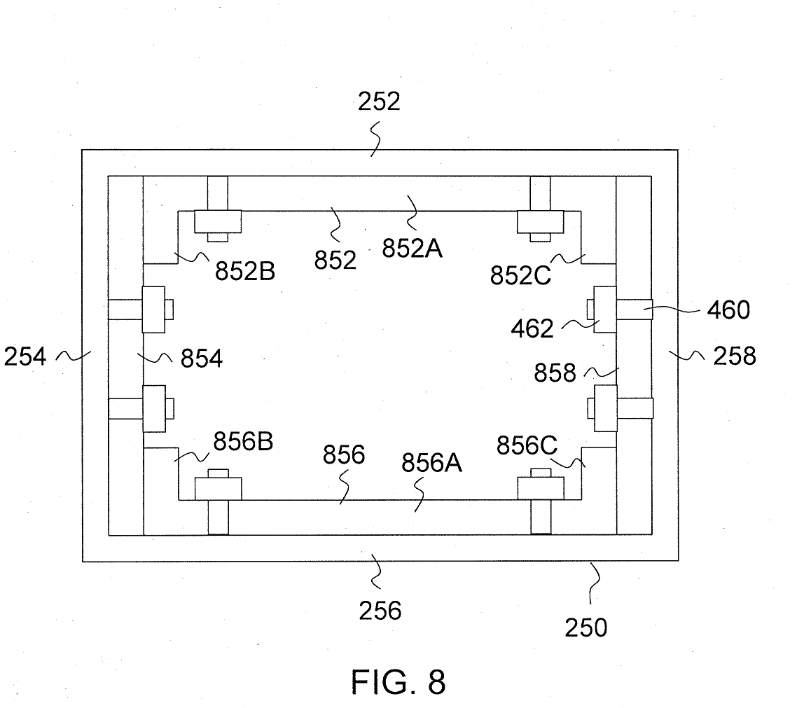

FIG. 8 shows a cut-away end view of a vapor transport deposition chamber 250 having removable shields 852, 854, 856, 858 affixed to the top wall 252, first side wall 254, bottom wall 256, and second side wall 258, respectively. The top removable shield 852 includes a middle horizontal portion 852A and a vertical portion 852B, 852C on each end. The bottom removable shield 856 includes similar horizontal 856A and vertical portions 856B, 856C. The vertical portions 852B, 852C, 856B, 856C fit against the sides of the removable shields 854, 858 to create a seal to keep vaporized semiconductor material from reaching the walls 252, 254, 256, 258 of the vapor transport deposition chamber 250. The removable shields 852, 854, 856, 858 are affixed to the walls by rods 460 and fasteners 462 similar to those shown in FIG. 4, but it should be noted that a combination of rods 460, fasteners 462, indentations 580, and/or stand-offs 664, 764 could be included in the manner shown in FIG. 4, 6, or 7, or a combination thereof. The heaters in the embodiment of FIG. 8 are enclosed in an indentation in one or more of the removable shields 852, 854, 856, 858, in the manner described with respect to FIG. 5, but could also be arranged behind the removable shields 852, 854, 856, 858, in the manner described with respect to FIGS. 6, 7A, 7B, if stand-offs 664, 764 are used.

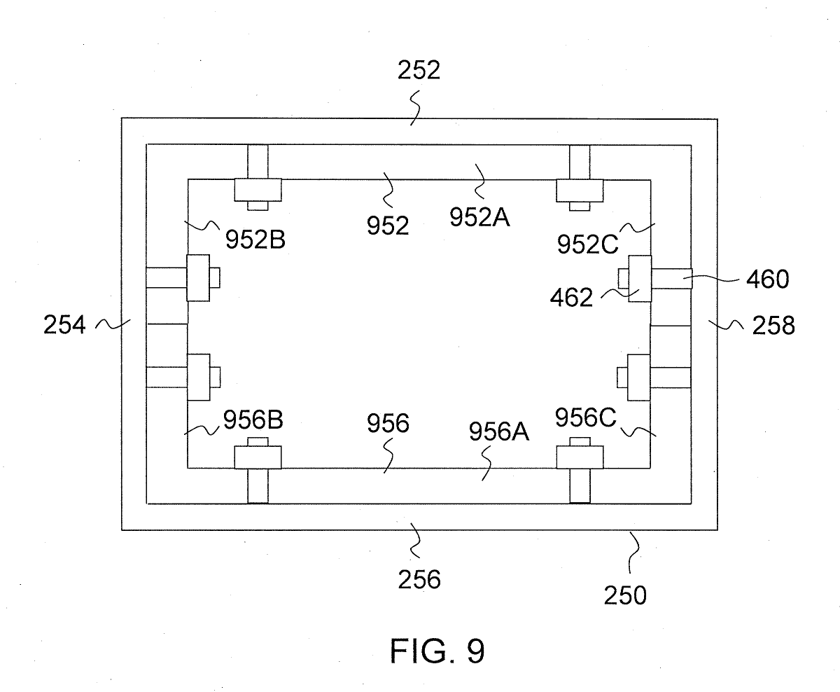

FIG. 9 shows a cut-away end view of a vapor transport deposition chamber 250 having removable shields 952, 954, 956, 958 affixed to the top wall 252, first side wall 254, bottom wall 256, and second side wall 258, respectively. The top removable shield 952 includes a middle horizontal portion 952A and a vertical portion 952B, 952C on each end. The bottom removable shield 956 includes similar horizontal 956A and vertical portions 956B, 956C. The vertical portions 952B, 952C, 956B, 956C extend the length of the side walls 254, 258 to fit against each other and cover the side walls 254, 258 without the use of additional plates. The removable shields 852, 854, 856, 858 are affixed to the walls by rods 460 and fasteners 462 similar to those shown in FIG. 4, but it should be noted that a combination of rods 460, fasteners 462, indentations 580, and/or stand-offs 664, 764 could be included in the manner shown in FIG. 4, 6, or 7, or a combination thereof. The heaters in the embodiment of FIG. 9 are enclosed in an indentation in one or more of the removable shields 852, 854, 856, 858, in the manner described with respect to FIG. 5, but could also be arranged behind the removable shields 852, 854, 856, 858, in the manner described with respect to FIGS. 6, 7A, 7B, if stand-offs 664, 764 are used.

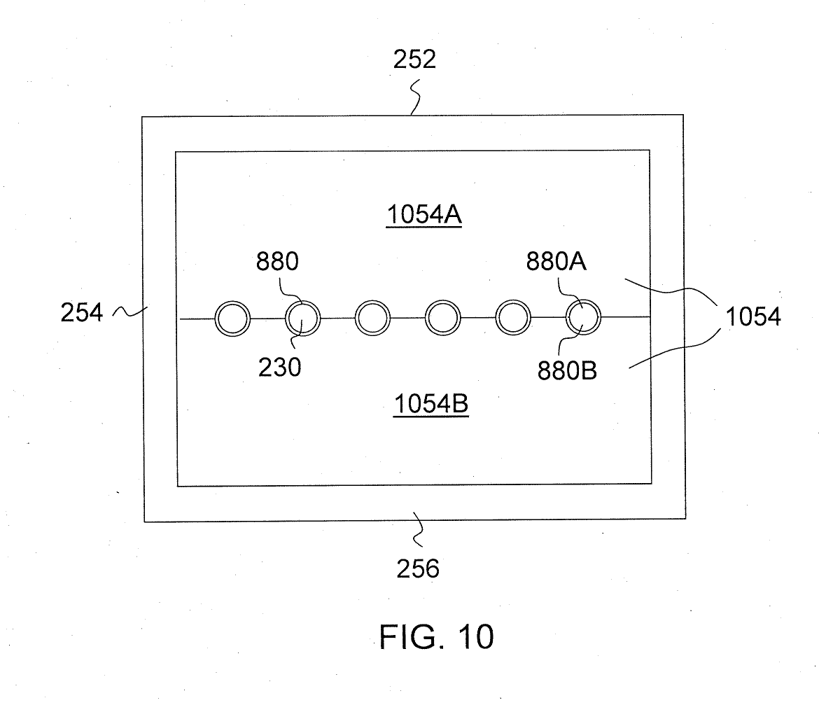

FIG. 10 shows a cut-away side view of a vapor transport deposition chamber 250. The removable shield 1054 is arranged adjacent to the first side wall 254 and is made up of a top piece 1054A and a bottom piece 1054B. The top piece 1054A includes a number of cutouts 880A arranged at the bottom of the top piece 1054A and the bottom piece 1054B includes a number of cutouts 880B at the top of the bottom piece 1054B. The cutouts 880A, 880B are arranged so that when the top piece 1054A and bottom piece 1054B abut one another, the cutouts 880A, 880B form a space 880 between the top piece 1054A and bottom piece 1054B that allows the rollers 230 to extend to the wall 254. In one aspect, the rollers 230 may be coupled to the wall 254. In another aspect, the rollers 230 may be located in close proximity to the wall 254. In other embodiments, including those described above with regard to FIGS. 4-9, the rollers 230 may be located far enough from the walls so that cutouts are not necessary.

The removable shields described above prevent vaporized material, e.g. semiconductor material, from reaching the walls of the vapor transport deposition chamber. The deposited material that does not adhere to the substrate glass will adhere to the shields rather than the walls of the chamber. The lack of buildup on the walls and heating elements of the vapor transport deposition chamber reduces the amount of time the chamber is down for a required periodic maintenance to remove material buildup. During a periodic maintenance cycle of the tool, the removable shields can be removed and replaced with a different set of clean removable shields. In another embodiment, the same set of removable shields can be removed, cleaned, and then reinstalled in the chamber. The used removable shields can be sealed in containers for transport to a controlled environment for cleaning.

Furthermore, by protecting the heater elements within the chamber from buildup using the removable shields, the heater elements will no longer require cleaning and therefore will allow for longer production runs. In addition, since the heater elements will not be exposed to corrosion, they may have an increased lifetime of operation. Yet another benefit of using the replaceable shields is better contamination control of the deposition material since the removable shields can be cleaned in a location designed especially for that purpose.

Although various aspects discussed herein show the removable shields arranged in a vapor transport deposition chamber, it should be understood that the removable shields could alternatively or additionally be arranged inside post deposition chambers. Furthermore, it should be understood that the features shown and described above in the various aspects may be combined with each other in any logical combination.

Details of one or more embodiments are set forth in the accompanying drawings and description. Other features, objects, and advantages will be apparent from the description, drawings, and claims. Although a number of embodiments of the invention have been described, it will be understood that various modifications may be made without departing from the spirit and scope of the invention. Also, it should also be understood that the appended drawings are not necessarily to scale, presenting a somewhat simplified representation of various features and basic principles of the invention.

What is claimed as new and desired to be protected by Letters Patent of the United States is:

1. A vapor deposition system comprising:
a vapor transport deposition chamber comprising a top wall, a bottom wall, a first side wall, and a second side wall;
a mechanism for distributing vaporized material arranged inside the vapor transport deposition chamber; and
at least one removable shield arranged inside the vapor transport deposition chamber and associated with at least one of said walls for protecting said associated wall from vaporized material.

2. The vapor deposition system of claim 1, further comprising a plurality of removable shields arranged inside the vapor transport deposition chamber and associated with a plurality of said walls.

3. The vapor deposition system of claim 1, further comprising a plurality of rollers arranged within the vapor transport deposition chamber for transporting a substrate through the vapor transport deposition chamber.

4. The vapor deposition system of claim 3, wherein at least one of the removable shields is affixed to a side wall and comprises a top piece and a bottom piece, the top piece comprising a plurality of cutouts arranged at the bottom of the top piece and the bottom piece comprising a plurality of cutouts arranged at the top of the bottom piece, and wherein the rollers extend through the cutouts of the top piece and the bottom piece.

5. The vapor deposition system of claim 2, wherein the plurality of removable shields comprises a first removable shield affixed to the top wall and a second removable shield affixed to the bottom wall.

6. The vapor deposition system of claim 5, wherein the plurality of removable shields further comprises a third removable shield affixed to the first side wall and a fourth removable shield affixed to the second side wall.

7. The vapor deposition system of claim 5, wherein the first removable shield comprises a horizontal portion, a first vertical portion extending downwards from a first end of the horizontal portion, and a second vertical portion extending downwards from a second end of the horizontal portion.

8. The vapor deposition system of claim 7, wherein the second removable shield comprises a horizontal portion, a first vertical portion extending upwards from a first end of the horizontal portion, and a second vertical portion extending upwards from a second end of the horizontal portion.

9. The vapor deposition system of claim 8, wherein the first vertical portion of the first removable shield contacts the first vertical portion of the second removable shield, and wherein the second vertical portion of the first removable shield contacts the second vertical portion of the second removable shield.

10. The vapor deposition system of claim 7, wherein the plurality of removable shields further comprises a third removable shield affixed to the first side wall and a fourth removable shield affixed to the second side wall, wherein the first vertical portion of the first removable shield contacts the third removable shield, and wherein the second vertical portion of the first removable shield contacts the fourth removable shield.

11. The vapor deposition system of claim 2, further comprising a plurality of rods affixed to one or more of the walls of the vapor transport deposition chamber for affixing a respective removable shield.

12. The vapor deposition system of claim 11, further comprising a plurality of fasteners for affixing the removable shields to one or more of the walls of the vapor transport deposition chamber by attaching the fasteners to the rods.

13. The vapor deposition system of claim 12, wherein the plurality of rods are threaded shafts and wherein the plurality of fasteners are bolts.

14. The vapor deposition system of claim 11, wherein the plurality of rods do not extend through the walls of the vapor transport deposition chamber.

15. The vapor deposition system of claim 1, further comprising a heating element affixed to a wall of the vapor transport deposition chamber, wherein the at least one removable shield comprises an indentation in which the heating element is arranged when the at least one removable shield is affixed to the wall of the vapor transport deposition chamber.

16. The vapor deposition system of claim 1, further comprising a plurality of stand-offs arranged to prevent the at least one removable shield from directly contacting said associated wall.

17. The vapor deposition system of claim 16, further comprising a plurality of rods affixed to said associated wall, wherein the plurality of stand-offs are arranged on the plurality of rods.

18. The vapor deposition system of claim 16, wherein the plurality of stand-offs are affixed to at least one of the plurality of removable shields.

19. The vapor deposition system of claim 16, wherein the plurality of stand-offs are arranged to create a gap between the at least one removable shield and said associated wall, wherein the vapor deposition system further comprises a heating element affixed to said associated wall and arranged in the gap.

20. The vapor deposition system of claim 2, wherein the plurality of removable shields are formed of stainless steel.

21. The vapor deposition system of claim 2, wherein the plurality of removable shields are formed of carbon fiber.

22. A method of depositing a material on a substrate using a vapor deposition system, the method comprising:
introducing a vaporized material into a vapor transport deposition chamber, wherein the vapor transport deposition chamber comprises a top wall, a bottom wall, a first side wall, and a second side wall;
depositing a first portion of the vaporized material onto an object, and depositing a second portion of the vaporized material onto a first plurality of removable shields arranged inside the vapor transport deposition chamber; and
removing the first plurality of removable shields from the vapor transport deposition chamber.

23. The method of claim 22, further comprising sealing the first plurality of removable shields in a container and transporting the first plurality of removable shields in the container to a cleaning facility.

24. The method of claim 22, further comprising cleaning the first plurality of removable shields to remove the deposited vaporized material.

25. The method of claim 24, further comprising reinstalling the first plurality of removable shields back into a vapor transport deposition chamber after cleaning the first plurality of removable shields.

26. The method of claim 22, further comprising arranging a second plurality of removable shields inside the vapor transport deposition chamber after removing the first plurality of removable shields.

27. The method of claim 22, wherein the first plurality of removable shields are affixed to the walls of the vapor transport deposition chamber by fasteners which allow removal of the removable shields.
